(19) United States
(12) Patent Application Publication
(10) Pub. No.: US 2015/0036411 A1
(43) Pub. Date: Feb. 5, 2015

(54) SEMICONDUCTOR MEMORY DEVICE

(71) Applicant: PANASONIC CORPORATION, Osaka (JP)

(72) Inventors: Masanori SHIRAHAMA, Shiga (JP); Toshiaki KAWASAKI, Osaka (JP); Kazuhiro TAKEMURA, Shiga (JP); Yasuhiro AGATA, Osaka (JP)

(21) Appl. No.: 14/516,380

(22) Filed: Oct. 16, 2014

Related U.S. Application Data
(63) Continuation of application No. PCT/JP2013/003074, filed on May 14, 2013.

(30) Foreign Application Priority Data
May 29, 2012 (JP) 2012-121899

(51) Int. Cl. G11C 17/16

(52) U.S. Cl. CPC G11C 17/16
USPC 365/96; 365/154

(57) ABSTRACT

A semiconductor memory device includes a nonvolatile device array including write-once nonvolatile devices arranged in rows and columns, row select lines, a row control circuit connected to the row select lines, column select lines, a column control circuit connected to the column select lines, a flip-flop circuit provided at least on a side of the nonvolatile device array opposite to the row control circuit or on a side of the nonvolatile device array opposite to the column control circuit, and an inactivation unit configured to inactivate the row select lines or the column select lines based on a first control signal.

### CROSS-REFERENCE TO RELATED APPLICATIONS

This is a continuation of International Application No. PCT/JP2013/003074 filed on May 14, 2013, which claims priority to Japanese Patent Application No. 2012-121899 filed on May 29, 2012. The entire disclosures of these applications are incorporated by reference herein.

### BACKGROUND

The present disclosure relates to semiconductor memory devices including nonvolatile devices such as electric fuses.

In recent years, higher-function and higher-performance devices have been developed. Moreover, high security is required for information devices. In order to achieve higher functions and higher performance, microfabrication techniques are further advanced in state-of-the-art semiconductor devices. In the field of state-of-the-art semiconductor devices, in particular, such as system large scale integration (LSI), there are demands for high security, and thus it is a trend to embed security ID codes having a relatively large number of bits in the semiconductor devices.

In these fields, for the higher performance, in particular, the accuracy of the analog quantities are required to be increased. For example, a memory, a phase locked loop (PLL) circuit, an analog circuit, etc. which are element technologies mounted to the semiconductor device perform tuning or the like of a memory defect recovery circuit, a PLL, and an analog quantity, respectively. For higher accuracy of the tuning, it is a trend to inspect interiors of semiconductor devices by semiconductor manufacturer, and then also inspect shipped sets of the semiconductor devices.

A fuse element (hereinafter referred to as an “electric fuse”) made of a stacked structure including a polysilicon layer and a silicide layer is often used as a simple program element. Methods for cutting the electric fuse include applying a predetermined program potential to both ends of the electric fuse, thereby allowing a current to flow in a silicide layer, to make the silicide gather and increase the resistance of the electric fuse (for example, see Japanese Translation of PCT International Application No. H11-512879).

### SUMMARY

Electric fuses used for these semiconductor devices are required to have a larger number of bits than a conventional number of bits. Additionally, assurance of sufficient quality is required in shipped sets of the semiconductor devices. When the number of bits of the electric fuse is increased, the area of the semiconductor device increases. To reduce the increase in the area, an electric fuse array in which electric fuses are arranged in rows and columns is often formed. On the other hand, for the assurance of the sufficient quality of the shipped sets of the semiconductor devices, peripheral circuits of the semiconductor devices has to be inspected for a defect in addition to a defect caused by cutting the electric fuses. That is, how to inspect the peripheral circuit for a defect without cutting the electric fuse is a problem.

To solve the problem, the inspection circuit described below has been proposed (for example, see Japanese Unexamined Patent Publication No. H 07-045097). The conventional inspection circuit includes an address decode circuit configured to decode an address signal to obtain an address decode signal and output the address decode signal to a word line, a word line control circuit configured to select the address decode signal or a test data input signal based on a test select signal to output the address decode signal or a level set signal to the word line and sequentially output test data output signals by test clock signals in response to the test data input signal, a memory cell array from which a memory cell is selected based on the address decode signal or the level set signal, and an input/output control circuit configured to write or read a data signal via a bit line corresponding to the memory cell in the memory cell array.

However, when the inspection circuit is operated, a flow of a current may change the state of the electric fuse as a nonvolatile device configured to change its state only once, thereby cutting the electric fuse.

In view of the foregoing, it is an object of the present disclosure to provide a semiconductor memory device capable of performing an inspection without destructing the nonvolatility of nonvolatile devices arranged in rows and columns. To achieve the object, the present disclosure provides the following features. For example, a semiconductor memory device includes: a nonvolatile device array including write-once nonvolatile devices arranged in rows and columns; one or more row select lines corresponding to rows of the nonvolatile device array; a row control circuit connected to one ends of the row select lines; one or more column select lines corresponding to columns of the nonvolatile device array; a column control circuit connected to one ends of the column select lines; a flip-flop circuit provided at least on a side of the nonvolatile device array opposite to the row control circuit or on a side of the nonvolatile device array opposite to the column control circuit; and an inactivation unit configured to inactivate the row select lines or the column select lines based on a first control signal.

With this configuration, under normal use conditions of the nonvolatile device including, for example, an electric fuse, activating the row select lines and the column select lines allows cutting operation, and during inspection, the row select lines or the column select lines are inactivated, so that the cutting operation is no longer performed. That is, during the inspection, the nonvolatility of the nonvolatile device is not destructed. Therefore, the row select lines or the column select lines under practical use conditions are activated, and the electric potentials of the row select lines or the column select lines can be verified by the flip-flop circuit. Here, the flip-flop circuit is arranged at least on a side of the column select lines opposite to the column control circuit or on a side of the row select lines opposite to the row control circuit. Thus, the flip-flop circuit can inspect a route from at least one of the control circuits to the flip-flop circuit via the nonvolatile device array. Thus, a short circuit formed between interconnects in the nonvolatile device array can also be externally detected, so that costs for the inspection can be reduced, and the high quality of the semiconductor memory device can be maintained. The inactivation unit, the flip-flop circuit, etc. can be implemented in a relatively small-scale circuit and in a relatively small area, so that the semiconductor memory device can be fabricated with low costs.

The inactivation unit may include a predecode signal generation circuit configured to inactivate a predecode signal to inactivate a corresponding one of the row select lines or a corresponding one of the column select lines, the predecode signal logically transitioning based on the first control signal.

With this configuration, the inactivation unit includes the predecode signal generation circuit. A predecode signal output from the predecode signal generation circuit logically transitions based on the first control signal. The predecode signal transitions to an inactive state, so that the row select line or the column select line are inactivated. Thus, around the nonvolatile device array, a driver circuit section of the row select lines and the column select lines, does not necessary to include a dedicated circuit, or the like for inactivating the select lines. That is, a test circuit includes no excessive area, and thus the semiconductor memory device can be fabricated with low costs.

The predecode signal generation circuit may inactivate the predecode signal based on the first control signal and a second control signal for selecting the nonvolatile device array.

With this configuration, the predecode signal generation circuit can inactivate the predecode signal by logically combining two control signals. Here, since the second control signal is a control signal for selecting the nonvolatile device array, it is not necessary to provide a circuit or the like to further inactivate the signal predecoded by the second control signal. Thus, the circuit area can be further reduced, and the configuration of the circuit can be simplified, in particular, the predecode signal generation circuit can be configured at an input first stage of a control signal.

The predecode signal generation circuit may inactivate the predecode signal based on a first synchronous signal and the first control signal.

With this configuration, with generalization of a control method of synchronous memory array by clock input is generalized, the predecode signal generation circuit is applicable to a method for generating a predecode signal from the clock input when the predecode signal is not generated by only inputting the first control signal. That is, the row select lines or the column select lines can be inactivated by logically combining the first control signal and the first synchronous signal as the clock input. Thus, it is not necessary to provide a circuit or the like to further inactivate a signal predecoded by the clock input.

The semiconductor memory device further includes: an open unit configured to open the column select lines, excluding one of the column select lines, when the column select lines are not inactivated, or the row select lines, excluding one of the row select lines, when the row select lines are not inactivated.

With this configuration, cutting operation can be stopped by inactivating the row select lines or the column select lines. Here, it is possible to open the row select lines, excluding one of the row select lines, when the row select lines are not inactivated, or the column select lines, excluding one of the column select lines, when the column select lines are not inactivated. For example, when one of the row select lines is active and at the high level, the other inactive row select lines once can transition from the low level to an open state. Thus, even when one select line does not reach the low level, or the inactive row select lines which should be at the low level do not reach the high level due to a short circuit or the like of interconnects having a resistance value in the nonvolatile device array, the abnormality in the nonvolatile device array can be detected by reading out of the electric potentials of all the row select lines to the flip-flop circuit, thereby contributing to maintenance of the quality.

The open unit includes n-type MIS transistors each having a drain connected to a corresponding one of the row select lines and a gate receiving a signal obtained by logically combining a first synchronous signal and a third control signal.

With this configuration, even when access to the nonvolatile device array is started by a synchronous signal, for example, the active one of the row select lines transitions to the high level, the electric potentials of the inactive row select lines once transitions to the low level, and the row select lines can then be open during the access to the nonvolatile device array. Thus, the open unit can have a further simplified configuration.

The open unit may change gate potentials of the n-type MIS transistors to a low level to open the row select lines, excluding an active one of the row select lines.

With this configuration, the active one of the row select lines transitions to the high level, the electric potentials of the inactive row select lines once transition to the low level, and the row select lines can then be open only during the access to the nonvolatile device array.

The open unit includes n-type MIS transistors each having a drain connected to a corresponding one of the column select lines and a gate receiving a signal obtained by logically combining a first synchronous signal and a third control signal.

With this configuration, even when access to the nonvolatile device array is started by a synchronous signal, for example, the active one of the column select lines transitions to the high level, the electric potentials of the inactive column select lines once transitions to the low level, and the column select lines can then be open only during the access to the nonvolatile device array. Thus, the open unit can have a further simplified configuration. The open unit may change gate potentials of the n-type MIS transistors to a low level to open the column select lines, excluding an active one of the column select lines.

With this configuration, the active one of the column select lines transitions to the high level, the electric potentials of the inactive column select lines once transition to the low level, and the column select lines can then be open during the access to the nonvolatile device array.

The flip-flop circuit may latch electric potentials of the row select lines or the column select lines based on a fourth control signal.

With this configuration, even while write operation or read operation is being performed on the nonvolatile device array, or even while the nonvolatile device array is not operating, the state of at least the row select lines or the column select lines of the nonvolatile device array can be detected by the flip-flop circuit.

The flip-flop circuit may include flip-flop circuits provided on a side of the nonvolatile device array opposite to the row control circuit and on a side of the nonvolatile device array opposite to the column control circuit.

With this configuration, the state of both the row select lines and the column select lines can be detected by the flip-flop circuits.

The nonvolatile device may be an electric fuse made of a gate material of a transistor.

With this configuration, an electric fuse, as a write-once nonvolatile device, whose state is changed by a flow of a current can be made of a gate material of a transistor. Thus, the nonvolatile device can be easily fabricated, and the cost of the nonvolatile device can be reduced.

According to the present disclosure, with the demand for a leading process in which progress is being made for further miniaturization, security for which functions and performance are improved, etc. the area of the semiconductor memory device including the nonvolatile device array can be reduced. Even when in order to improve the accuracy of the analog quantity, not only trimming by the semiconductor manufacturer, but also trimming or cutting shipped sets of semiconductor memory devices are performed, the manufacturing cost of the semiconductor memory device can be reduced and the quality of the semiconductor memory device can be maintained and increased while an increase in circuit scale is reduced. Stable inspection is possible without destructing the nonvolatile devices, etc., so that the quality of the shipped product can be increased.

### BRIEF DESCRIPTION OF THE DRAWINGS

FIG. 1 is a view illustrating an example configuration of a semiconductor memory device according to an embodiment.

FIG. 2 is a view illustrating a first example configuration of a predecode signal generation circuit included in a row control circuit of FIG. 1.

FIG. 3 is a view illustrating a second example configuration of the predecode signal generation circuit included in the row control circuit of FIG. 1.

FIG. 4 is a view illustrating a third example configuration of the predecode signal generation circuit included in the row control circuit of FIG. 1.

FIG. 5 is a view illustrating an example configuration of an open unit of a column select line of FIG. 1.

FIG. 6 is a view illustrating an example configuration of an open unit of a row select line of FIG. 1.

FIG. 7 is a waveform in diagram illustrating first operation of the semiconductor memory device of FIG. 1.

FIG. 8 is a waveform diagram illustrating second operation of the semiconductor memory device of FIG. 1.

### DETAILED DESCRIPTION

### Embodiment

A semiconductor memory device according to an embodiment of the present disclosure will be described below with reference to the drawings.

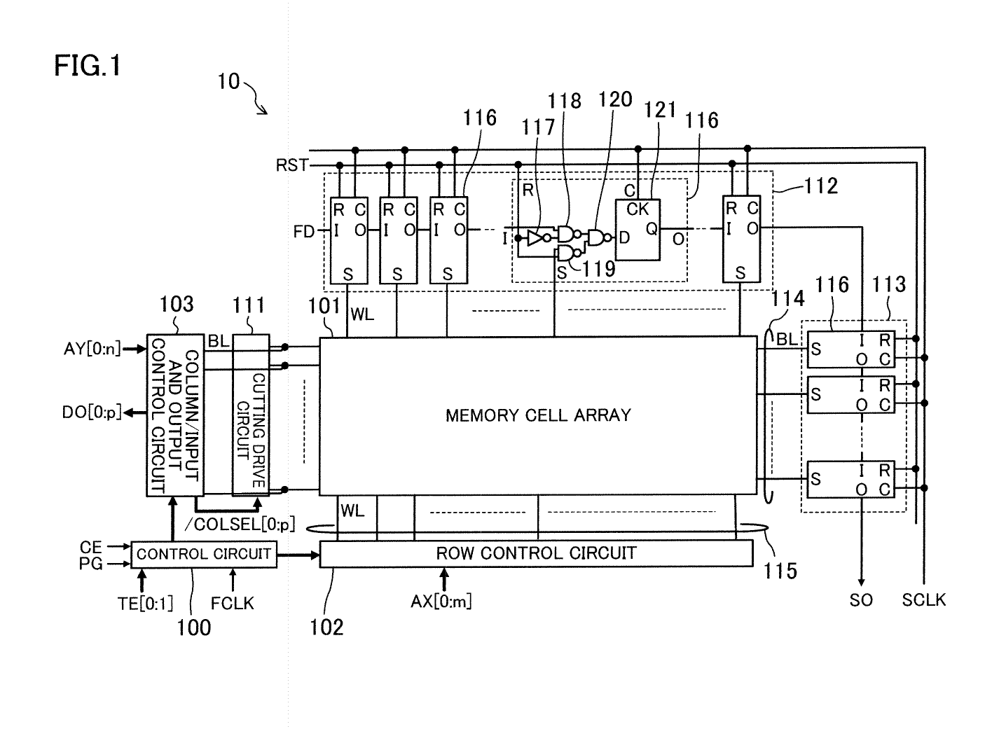

FIG. 1 is a view illustrating an example configuration of the semiconductor memory device according to the embodiment. A semiconductor memory device 10 illustrated in FIG. 1 is a semiconductor memory device including a memory cell array having a nonvolatile device array in which write-once nonvolatile devices are arranged in rows and columns. In the present embodiment, a case in which an electric fuse made of a gate material of a transistor is used as the nonvolatile device will be described.

The semiconductor memory device 10 includes a memory cell array 101 having an electric fuse array including electric fuses arranged in rows and columns, a row control circuit 102 connected to the memory cell array 101 by row select lines WL, a cutting drive circuit 111 connected to the memory cell array 101, a column/input and output control circuit 103 (column control circuit) connected to the memory cell array 101 and the cutting drive circuit 111 by column select lines BL, a control circuit 100 connected to the row control circuit 102 and the column/input and output control circuit 103, a row selection scan flip-flop circuit 112 connected to the memory cell array 101, and a column selection scan flip-flop circuit 113 connected to the memory cell array 101.

The control circuit 100 receives a chip enable signal CE serving as a select signal for selecting the memory cell array 101, a program enable signal PG, and test mode enable signals TE[0:1] (1E[0:1] is an abbreviation of TE[0], TE[1], this abbreviation system is used in the following description) as input signals, and receives a synchronous signal FCLK serving as a first synchronous signal as a clock input. Output signals of the control circuit 100 control the row control circuit 102 and the column/input and output control circuit 103. In the present embodiment, the memory cell array 101 is selected, so that the electric fuse array provided in the memory cell array 101 is selected.

The row control circuit 102 receives input address signals AX[0:m] (m is a positive integer) and is controlled by the output signal from the control circuit 100. The row control circuit 102 decodes addresses for the memory cell array 101, and outputs row select signals 115 to the row select lines WL. In this way, the electric fuse array in the memory cell array 101 is selected.

The column/input and output control circuit 103 receives input address signals AY[0:n] (n is a positive integer), and reads and writes data from and to memory cells included in the memory cell array 101. When the column/input and output control circuit 103 reads data, the column/input and output control circuit 103 generates column signals 114, and outputs data, which has been read from the memory cells (electric fuses) and output to column select lines BL, as data output signals DO[0:p] (p is a positive integer). On the other hand, when the column/input and output control circuit 103 writes data, the column/input and output control circuit 103 outputs signals /COLSEL[0:p] to the cutting drive circuit 111.

The memory cell array 101 includes a plurality of memory cells each including an electric fuse formed of the gate of a MIS transistor and an n-type MIS transistor whose gate is configured to receive the row select signal 115. Each memory cell is connected to a corresponding one of the row select lines WL and a corresponding one of the column select lines BL.

When control by the control circuit 100 allows the column/input and output control circuit 103 to perform write operation on the memory cells, the cutting drive circuit 111 drives electric potentials necessary to cut the electric fuses to the column select lines BL of the memory cells based on the signals /COLSEL[0:p]

The row selection scan flip-flop circuit 112 latches decoded electric potentials of the row select lines WL. The column selection scan flip-flop circuit 113 latches decoded electric potentials of the column select lines BL. In the present embodiment, the row selection scan flip-flop circuit 112 and the column selection scan flip-flop circuit 113 are configured such that an output of the row selection scan flip-flop circuit 112 is connected to an input of the column selection scan flip-flop circuit 113.

A control signal RST is input to the row selection scan flip-flop circuit 112 and the column selection scan flip-flop circuit 113 so that flip-flop circuits 116 in the row selection scan flip-flop circuit 112 latch the row select signals 115 of the row select lines WL and flip-flop circuits 116 in the column selection scan flip-flop circuit 113 latch the column signals 114 of the column select lines BL. A synchronous signal SCLK is also input to the row selection scan flip-flop circuit 112 and the column selection scan flip-flop circuit 113 to output latched data in the row selection scan flip-flop circuit 112 and the column selection scan flip-flop circuit 113.

Here, the flip-flop circuits 116 each of which is a unit transistor included in the row selection scan flip-flop circuit 112 and the column selection scan flip-flop circuit 113 will be described in detail.

Each flip-flop circuit 116 includes an I terminal as a data input, an R terminal for receiving the control signal RST, an S terminal for receiving the electric potential of the row select line WL or the column select line BL, a C terminal for receiving the synchronous signal SCLK, an O terminal as a data output, an inverter circuit 117, a selector circuit including NAND circuits 118,119,120, and a DQ flip-flop circuit 121.

The inverter circuit 117 inverts the control signal RST and outputs the resulting signal. The NAND circuit 118 receives the output from the inverter circuit 117 and an output from the 0 terminal of the immediately previous flip-flop circuit 116. The NAND circuit 119 receives an input to the S terminal and the control signal RST. The NAND circuit 120 receives outputs of the NAND circuits 118 and 119.

The DQ flip-flop circuit 121 is the C terminal of the flip-flop circuit 116, and transfers an input signal from a D terminal serving as an input of the DQ flip-flop circuit 121 to a Q terminal serving as an output of the DQ flip-flop circuit 121 in response to the synchronous signal SCLK input to a CK terminal of the DQ flip-flop circuit 121. In FIG. 1, the S terminals of the flip-flop circuits 116 are connected to end portions of the row select lines WL and the column select lines BL on sides of the memory cell array 101 opposite to the row control circuit 102 and opposite to the column/input and output control circuit 103.

When the control signal RST input to an R terminal transitions to a high level, each flip-flop circuit 116 transmits a signal input to the S terminal to the DQ flip-flop circuit 121 and stores the electric potential of the signal in the DQ flip-flop circuit 121. The flip-flop circuits 116 are configured such that when the control signal RST to be input to the flip-flop circuits 116 transitions to a low level, the I terminal of each flip-flop circuit 116 receives an output from the 0 terminal of the immediately previous flip-flop circuit 116, such that the synchronous signal SCLK clock input to the flip-flop circuit 116 is sequentially transferred to the next-stage flip-flop circuit 116.

A signal FD is input to the first-stage flip-flop circuit 116, and a signal SO is output from the final-stage flip-flop circuit 116 to an outside. With this configuration, even while the memory cell array 101 is performing read operation and write operation, or the memory cell array 101 is not operating, electric potentials of the row select signals 115 of the row select lines WL and the column signals 114 of the column select lines BL are arbitrarily latched, so that the signal SO can be output to the outside.

### First Example Configuration of Predecode Signal Generation Circuit

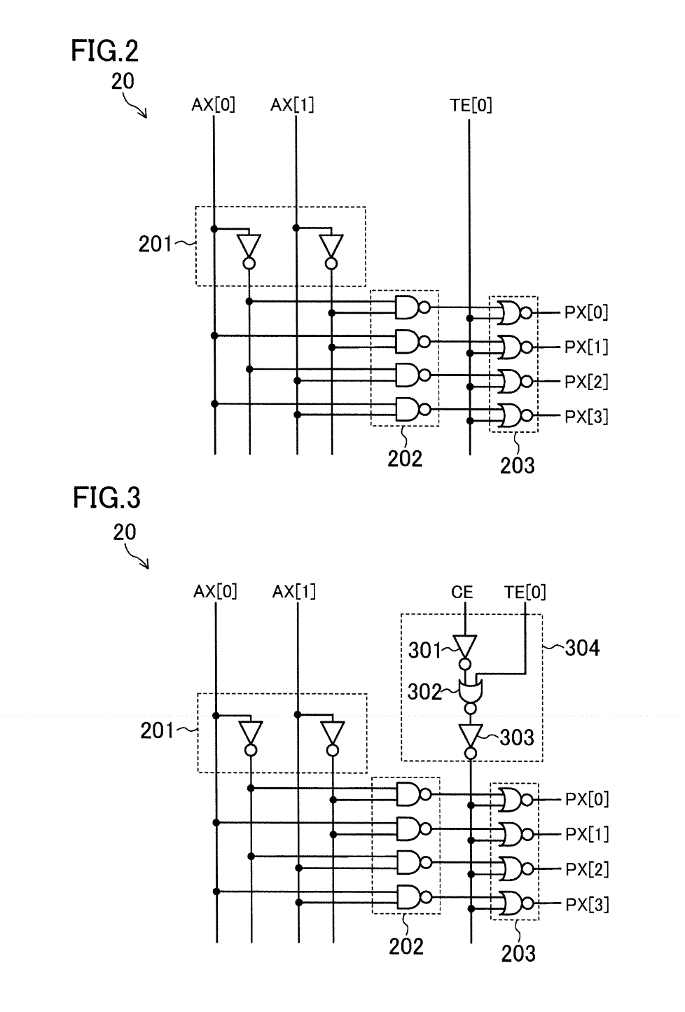

FIG. 2 is a view illustrating a first example configuration of a predecode signal generation circuit included in the row control circuit in the semiconductor memory device of FIG. 1.

As illustrated in FIG. 2, the predecode signal generation circuit 20 includes inverter circuits 201, NAND circuits 202, and NOR circuits 203.

In FIG. 2, the input address signal AX[0] is one of the input address signals AX[0:m] input to the row control circuit 102 in FIG. 1 which corresponds to alignment 0, and the input address signal AX[1] is one of the input address signals AX[0:m] which corresponds to alignment 1.

In the predecode signal generation circuit 20, the inverter circuits 201 generate inverted electric potentials in order to decode the input address signals AX[0], AX[1]. Positive and negative signals are input to the NAND circuits 202 so that the signals can be decoded. Each of outputs of the NAND circuits 202 is input to a corresponding one of the NOR circuits 203. The test mode enable signal TE[0] (first control signal) in the semiconductor memory device is input to the NOR circuits 203.

The above configuration is implemented for every one of the input address signals AX[0:m], thereby forming a row predecode signal generation circuit. When the test mode enable signal TE[0] is at a low level, predecode signals PX are signals obtained by decoding addresses specified by the input address signals AX[0:m]. On the other hand, when the test mode enable signal TE[0] is at a high level, all the predecode signals PX are at the low level, and are inactive.

### Second Example Configuration of Predecode Signal Generation Circuit

FIG. 3 is a view illustrating a second example configuration of the predecode signal generation circuit included in the row control circuit in the semiconductor memory device of FIG. 1. In the first example configuration illustrated in FIG. 2, the test mode enable signal TE[0] is directly input to one terminal of each NOR circuit 203. In contrast, the second example configuration illustrated in FIG. 3 is different from the first example configuration in that a logic circuit 304 receives a chip enable signal CE (second control signal) and the test mode enable signal TE[0], and an output signal from the logic circuit 304 is input to one terminal of each NOR circuit 203 instead of the test mode enable signal TE[0] in FIG. 2. In FIG. 3, the same reference numerals as those shown in FIG. 2 are used to represent elements having functions similar to those in the first example configuration illustrated in FIG. 2.

The predecode signal generation circuit 20 is configured to generate predecode signals PX[0:3] in response to the chip enable signal CE which is a select signal of the memory cell array 101.

Specifically, the logic circuit 304 includes an inverter circuit 301 configured to receive the chip enable signal CE, a NOR circuit 302 configured to receive a signal which is output from the inverter circuit 301 and is obtained by inverting the chip enable signal CE and the test mode enable signal TE[0], and an inverter circuit 303 configured to receive a signal output from the NOR circuit 302.

The inverter circuit 303 outputs a signal obtained by inverting the output signal of the NOR circuit 302. The inverted signal is an input signal to one terminal of each NOR circuit 203. Generally, when a predecode signal is generated by a chip enable signal CE, an inversion signal of the chip enable signal CE is input to one input of the NOR circuit 203, thereby generating the predecode signal. However, the second example configuration is such a configuration that the predecode signals PX[0:3] are inactivated by logically combining the test mode enable signal TE[0] and the chip enable signal CE, and thus, the second example configuration has the configuration of the logic circuit 304 as illustrated in FIG. 3.

The logic circuit 304 may be provided in the row control circuit 102, or may be provided in, for example, the control circuit 100. When the logic circuit 304 is provided in the control circuit 100, the output from the logic circuit 304 is supplied to the row control circuit 102. Thus, the required area of a region for forming the row control circuit 102 can be small.

### Third Example Configuration of Predecode Signal Generation Circuit

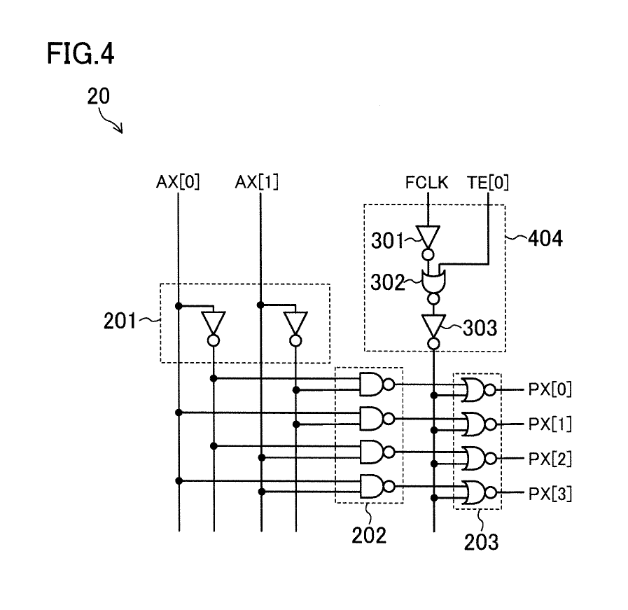

FIG. 4 is a view illustrating a third example configuration of the predecode signal generation circuit included in the row control circuit in the semiconductor memory device of FIG. 1. In the second example configuration illustrated in FIG. 3, the chip enable signal CE is input to the inverter circuit 301. In contrast, the third example configuration illustrated in FIG. 4 is different from the second example configuration in that the synchronous signal FCLK is input to an inverter circuit 301 instead of the chip enable signal CE of FIG. 3. In FIG. 4, the same reference numerals as those shown in FIG. 3 are used to represent elements having functions similar to those in the second example configuration illustrated in FIG. 3.

A predecode signal generation circuit 20 is configured such that predecode signals PX[0:3] are generated by the synchronous signal FCLK supplied to the control circuit 100.

Specifically, a logic circuit 404 includes an inverter circuit 301 configured to receive the synchronous signal FCLK, a NOR circuit 302 configured to receive a signal which is output from the inverter circuit 301 and is obtained by inverting the synchronous signal FCLK and the test mode enable signal TE[0], and an inverter circuit 303 configured to receive a signal output from the NOR circuit 302.

The inverter circuit 303 outputs a signal obtained by inverting the output signal of the NOR circuit 302. The inverted signal is an input signal to one terminal of each NOR circuit 203. Generally, when a predecode signal is generated by a synchronous signal FCLK, an inversion signal of the synchronous signal FCLK is input to one input of each NOR circuit 203, thereby generating the predecode signal. However, the third example configuration is such a configuration that the predecode signals PX[0:3] are inactivated by logically combining the test mode enable signal TE[0] and the synchronous signal FCLK, and thus, the third example configuration has the configuration of the logic circuit 404 as illustrated in FIG. 4.

The logic circuit 404 may be provided in the row control circuit 102, or may be provided in, for example, the control circuit 100. When the logic circuit 404 is provided in the control circuit 100, the output from the logic circuit 404 is supplied to the row control circuit 102. Thus, the required area of a region for forming the row control circuit 102 can be small.

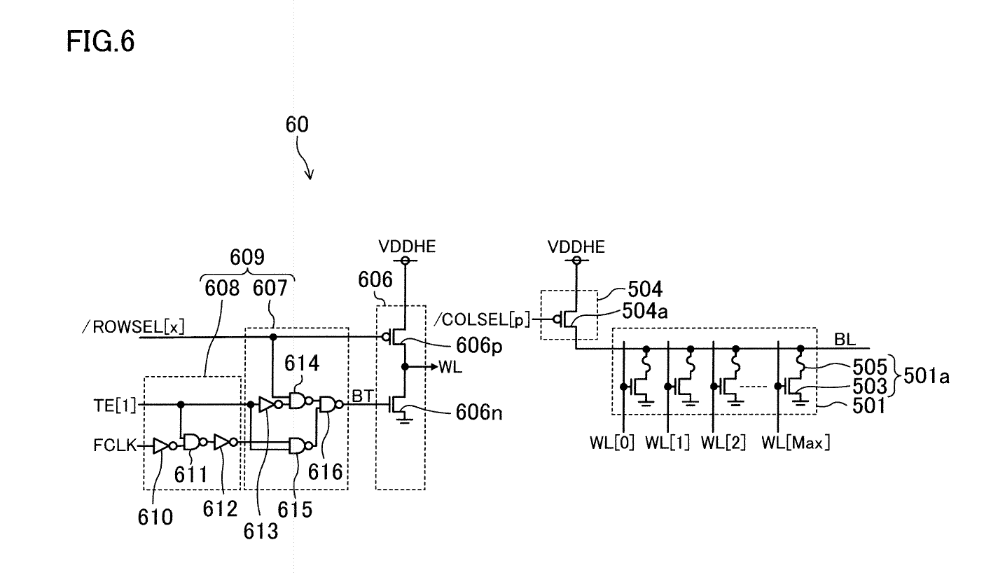

In FIGS. 2-4, some configurations of the row predecode signal generation circuits are illustrated. These configurations can be applied to column predecode signal generation circuits. In this case, for example, the input address signals AX[0], AX[1] are respectively replaced with input address signals AY[0], AY[1], and the predecode signals PX[0:3] are replaced with predecode signals PY[0:3]. The predecode signal PY[0] corresponds to, for example, COLSEL[0] (see, for example, FIG. 6). A test mode enable signal TE[1] may be used as the first control signal.

As described above, with the configuration illustrated in FIGS. 1-4, the column select lines BL or the row select lines WL can be inactivated. Therefore, when the semiconductor memory device 10 is inspected, the row select lines WL or the column select lines BL are inactivated, so that the memory cells included in the memory cell array 101 are not activated. That is, the inspection can be performed without cutting the electric fuse.

The row selection scan flip-flop circuit 112 is disposed on a side of the memory cell array 101 opposite to the row control circuit 102. Thus, a route from the control circuit 100 to the row selection scan flip-flop circuit 112 via the row control circuit 102 and the memory cell array 101 can be inspected for a defect.

The column selection scan flip-flop circuit 113 is disposed on a side of the memory cell array 101 opposite to the column/input and output control circuit 103. Thus, a route from the control circuit 100 to the column selection scan flip-flop circuit 113 via the column/input and output control circuit 103 and the memory cell array 101 can be inspected for a defect.

The inspection can be performed using the scan flip-flop circuits 112, 113 having a relatively small circuit areas. Thus, the area of the inspection circuit can be reduced. The results of the inspection can be verified by, for example, externally monitoring outputs of the scan flip-flop circuits 112, 113.

As described above, semiconductor memory devices can be inspected with a simple configuration and with a reduced area by using an inactivation unit connected to a memory cell array having an electric fuse array, and configured to inactivate row select lines or column select lines, and a unit configured to sense the electric potentials of the row select lines or the column select lines, and thus the quality of the semiconductor memory devices can be maintained and improved.

### Example Configuration of Column Select Line Open Unit

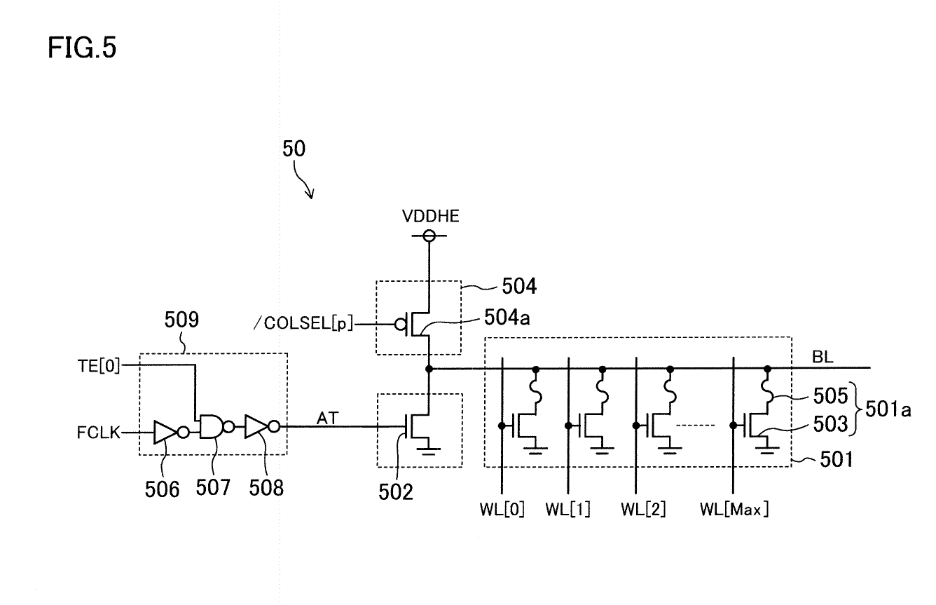

FIG. 5 is a view illustrating an example configuration of an open unit configured to open the column select line of the semiconductor memory device of FIG. 1. The column select line open unit 50 allows non-active ones of the column select lines BL to be open while all the row select lines WL are inactive. That is, the column select line open unit 50 allows the column select lines BL, excluding any one of the column select lines BL, to be open.

In FIG. 5, each of memory cells 501a in a memory cell group 501 includes an electric fuse 505 and an n-type MIS transistor 503.

One end of the electric fuse 505 is connected to the column select line BL, and the other end of the electric fuse 505 is connected to the drain of the n-type MIS transistor 503 configured to cut the electric fuse 505. The gate of the n-type MIS transistor 503 is connected to the row select line WL, and the source is connected to ground.

The column select line open unit 50 includes a cutting drive circuit 504, an n-type MIS transistor 502, and a column select line open circuit 509.

The cutting drive circuit 504 includes, for example, a p-type MIS transistor 504a. The source of the p-type MIS transistor 504a is connected to a high-voltage power supply VDDHE, the drain is connected to the column select line BL, and the gate is connected to an inversion signal /COLSEL[p] obtained by inverting a decode signal COLSEL[p]. The drain of the p-type MIS transistor 504a is connected to the drain of the n-type MIS transistor 502.

The drain of the n-type MIS transistor 502 is connected to the column select line BL, the source is connected to ground, and the gate is connected to an output signal AT from the column select line open circuit 509.

The column select line open circuit 509 includes an inverter circuit 506, a NAND circuit 507, and an inverter circuit 508. The output signal AT from the column select line open circuit 509 is generated by inputting a signal obtained by inverting the synchronous signal FCLK by the inverter circuit 506 and the test mode enable signal TE[0] serving as a third control signal to the NAND circuit 507, and by inverting an output from the NAND circuit 507 by the inverter circuit 508. The test mode enable signal TE[0] may be used as the first and third control signals.

When the test mode enable signal TE[0] is at a high level, as described above, the row control circuit 102 keeps all the electric potentials of the row select lines WL at a low level.

When the test mode enable signal TE[0] is at the high level, two input terminals of the NAND circuit 507 are both at the high level due to the inverter circuit 506 which inverts the electric potential of the synchronous signal FCLK. Thus, the output of the NAND circuit 507 are at the low level, and the output signal AT from the inverter circuit 508 once changes to the high level, so that the electric potential of the column select line BL once changes to the low level.

When the electric potential of the synchronous signal FCLK changes to the high level, the output signal AT changes to the low level, and the column select lines BL which have been changed to the low level and are inactive, that is, the column select lines BL, excluding an active one of the column select lines BL, are opened. Here, based on a result of decoding the inversion signal /COLSEL[p] obtained by inverting the decode signal COLSEL[p], the gate potential of the cutting drive circuit 504 is at the low level, and the active column select line BL is at a high electric potential of the power supply VDDHE.

Thus, when an access (in particular write operation) to the memory cell array 101 is caused, the column select lines BL1, excluding one of the column select lines BL, can be opened. When a defect such as a short circuit is caused in the memory cell array 101, the potential of the active column select line BL may not lower from the high level, but the potential of the inactive column select line BL in which the short circuit has been formed and which is open changes to the high level, so that the defect can be detected.

Although not shown, in the column select line open unit 50, the chip enable signal CE, which is a signal for selecting the memory cell array 101, may be used instead of the synchronous signal FCLK. When the test mode enable signal TE[0] is at the low level, the output signal AT is at the low level, so that interference with normal operation is prevented.

### Example Configuration of Row Select Line Open Unit

FIG. 6 is a view illustrating an example configuration of an open unit configured to open the row select line of the semiconductor memory device of FIG. 1. The row select line open unit 60 allows non-active ones of the row select lines WL to be open while all the column select lines BL are inactive. In FIG. 6, the same reference numerals as those shown in FIG. 5 are used to represent elements having functions similar to those illustrated in FIG. 5. In FIG. 6, in order to keep the uniformity, the test mode enable signal TE[1] is used as a signal to inactivate the column select line BL, that is, the first control signal to the column predecode signal generation circuit.

In FIG. 6, each of memory cells 501a in a memory cell group 501 includes an electric fuse 505 and an n-type MIS transistor 503. One end of the electric fuse 505 is connected to the column select line BL, and the other end of the electric fuse 505 is connected to the drain of the n-type MIS transistor 503 configured to cut the electric fuse 505. The gate of the n-type MIS transistor 503 is connected to the row select line WL, and the source is connected to ground.

The cutting drive circuit 504 includes a p-type MIS transistor 504a. The source of the p-type MIS transistor 504a is connected to a power supply VDDHE, the drain is connected to the column select line BL, and the gate is connected to an inversion signal /COLSEL[p] obtained by inverting a decode signal COLSEL[p].

The row select line open unit 60 includes a driver circuit 606 and a row select line open circuit 609 having a selector circuit 607 and a logic circuit 608.

The driver circuit 606 includes a p-type MIS transistor 606p and an n-type MIS transistor 606n, and generates an electric potential of the row select line WL.

The source of the p-type MIS transistor 606p is connected to the power supply VDDHE which will be an write electric potential of the memory cell array 101, the drain is connected to the row select line WL, and the gate is connected to an inversion signal /ROWSEL[x] obtained by inverting a decode signal ROWSEL[x] of the row select line WL.

The drain of the n-type MIS transistor 606n is connected to the row select line WL, the source is connected to ground, and the gate is connected to an output signal BT of the selector circuit 607.

The logic circuit 608 includes an inverter circuit 610, a NAND circuit 611, and an inverter circuit 612. The output signal from the logic circuit 608 is generated by inputting a signal obtained by inverting the synchronous signal FCLK by the inverter circuit 610 and the test mode enable signal TE[1] serving as a third control signal to the NAND circuit 611, and by inverting an output from the NAND circuit 611 by the inverter circuit 612. The test mode enable signal TE[1] may be used as the first and third control signals.

The selector circuit 607 includes an inverter circuit 613 configured to receive the test mode enable signal TE[1], a NAND circuit 614 configured to receive a signal (the inversion signal of the test mode enable signal TE[1]) output from the inverter circuit 613 and the inversion signal /ROWSEL[x] obtained by inverting the decode signal ROWSEL[x], a NAND circuit 615 configured to receive the test mode enable signal TE[1] and a signal output from the inverter circuit 612 of the logic circuit 608, and a NAND circuit 616 configured to receive signals output from the NAND circuit 614 and the NAND circuit 615. The output signal BT is output from the NAND circuit 616.

In the selector circuit 607, when the test mode enable signal TEM is input as a signal for performing select control, and the test mode enable signal TE[1] is at the low level, the inversion signal /ROWSEL[x] of the decode signal ROWSEL[x] is output as the output signal BT. On the other hand, when the test mode enable signal TE[1] is at the high level, a result of a logical AND operation of the test mode enable signal TE[1] and an inversion signal of the synchronous signal FCLK is output as the output signal BT.

When the test mode enable signal TE[1] is at the low level, the output signal BT input to the gate of the n-type MIS transistor 606n of the driver circuit 606 is the inversion signal /ROWSEL[x] of the decode signal ROWSEL[x], which results in normal decoding operation. On the other hand, when the test mode enable signal TE[1] is at the high level, the inversion signal of the synchronous signal FCLK is supplied to the gate of the n-type MIS transistor 606n. Thus, when the synchronous signal FCLK is at the low level, the output signal BT is at the high level, and the row select line WL is at the low level. On the other hand, when the synchronous signal FCLK is at the high level, the output signal BT is at the low level, so that the row select line WL is open. At this time, an active row select line WL is at an electric potential of the power supply VDDHE because the inversion signal /ROWSEL[x] of the decode signal ROWSEL[x] is input to the gate of the p-type MIS transistor 606p of the driver circuit 606. Thus, the electric potential of the active row select line WL is substantially equal to the power supply VDDHE, so that the inactive row select lines WL, that is, the row select lines WL, excluding the active row select line, are open. Thus, even in the case of a short circuit having a certain resistance value in the memory cell array 101, the abnormality can be detected by externally sensing the electric potentials of the row select lines WL, irrespective of whether the row select lines WL are active or inactive.

### First Operation of Semiconductor Memory Device

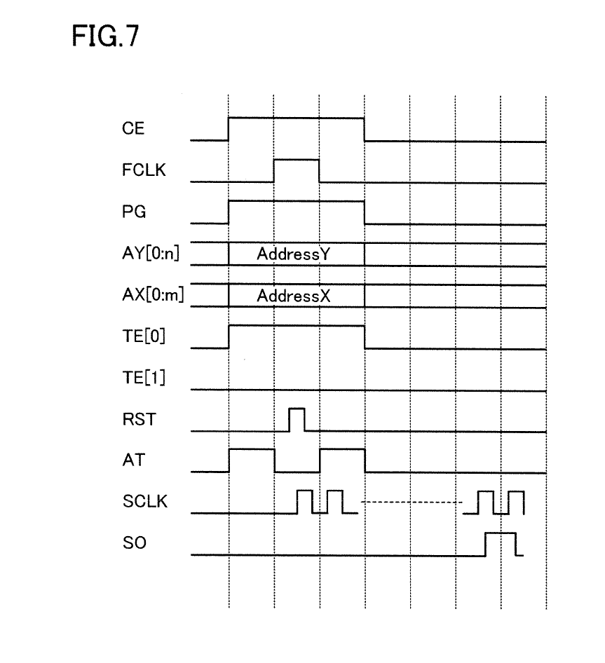

FIG. 7 is a waveform diagram illustrating first operation of the semiconductor memory device according to the embodiment. In particular, the waveform diagram illustrates operation in the case where the test mode enable signal TE[0] changes to the high level, and the row select lines WL are inactivated to detect an abnormality in the column select line BL. The waveform diagram illustrated in FIG. 7 is obtained in a configuration of the semiconductor memory device of FIG. 1 in which the predecode signal generation circuit 20 of FIG. 4 and the column select line open unit 50 of FIG. 5 are used. Names of the signals in FIG. 7 have been already described, and thus the description thereof is omitted.

The chip enable signal CE which will be a select signal of the memory cell array 101 (electric fuse array) changes to the high level indicating that the memory cell array 101 is selected, and concurrently, the program enable signal PG changes to the high level to start write operation. At this time, input address signals AY[0:n] and input address signals AX[0:m] are specified and input. The input address signals AY[0:n] and the input address signals AX[0:m] indicate addresses in the memory cell to which the write operation will be performed. When the test mode enable signal TE[0] is changed to the high level, the row select lines WL are inactivated.

At this time, the output signal AT, which will be the gate potential of the n-type MIS transistor 502 connected to the column select line BL of FIG. 5, changes to the high level. Thus, the electric potential of the column select line BL changes to the low level.

Next, when the synchronous signal FCLK supplied to the semiconductor memory device 10 changes to the high level, all the predecode signals PX are inactivated due to the configuration of FIG. 4. Thus, the electric potentials of all the row select lines WL change to the low level.

When the synchronous signal FCLK changes to the high level, the output signal AT changes to the low level. Thus, the column select lines BL are opened with the electric potentials of the column select lines BL remaining at the low level. Thereafter, when the control signal RST illustrated in FIG. 1 is changed to the high level, the electric potentials of the row select lines WL and the column select lines BL are latched by the scan flip-flop circuits 112, 113. The synchronous signal SCLK is input to the scan flip-flop circuits 112, 113, so that the electric potentials of the row select lines WL and the column select lines BL are output from the O terminal of the final-stage flip-flop circuit 116 as a signal SO.

Even in the case of a slight short circuit in which an active one of the column select lines BL has certain resistance, the above operation can detect the abnormality by sensing the electric potential of the signal SO output to the outside.

### Second Operation of Semiconductor Memory Device

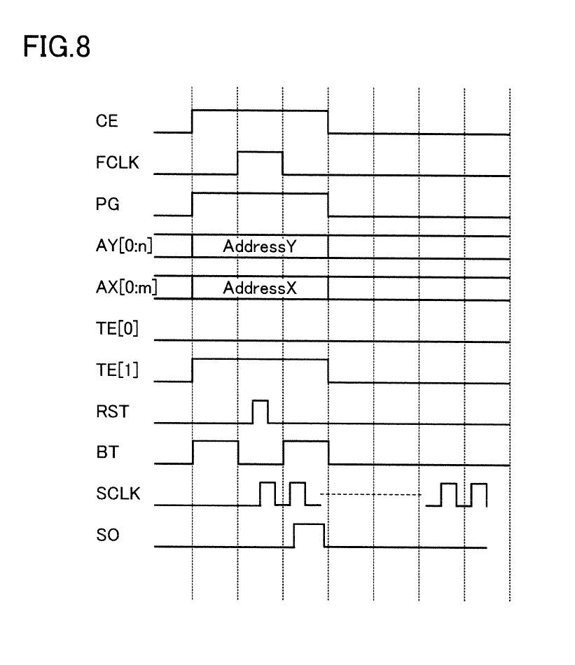

FIG. 8 is a waveform diagram illustrating second operation of the semiconductor memory device according to the embodiment of the present invention. In particular, the waveform diagram illustrates operation in the case where the test mode enable signal TE[1] changes to the high level, and the column select lines BL are inactivated to detect an abnormality in the row select line WL. The waveform diagram illustrated in FIG. 8 is obtained in a configuration of the semiconductor memory device of FIG. 1 in which the predecode signal generation circuit 20 of FIG. 4 is applied to the column predecode signal generation circuit, and the row select line open unit 60 of FIG. 6 is used. The signals in FIG. 8 have been already described, and thus the description thereof is omitted.

The chip enable signal CE which will be a select signal of the memory cell array 101 (electric fuse array) changes to the high level indicating that the memory cell array 101 is selected, and concurrently, the program enable signal PG changes to the high level to start write operation. At this time, input address signals AY[0:n] and input address signals AX[0:m] are specified and input. The input address signals AY[0:n] and the input address signals AX[0:m] indicate addresses in the memory cell to which the write operation will be performed. When the test mode enable signal TE[1] is changed to the high level, the column select lines BL are inactivated.

At this time, the output signal BT, which will be the gate potential of the n-type MIS transistor 606n connected to the row select line WL of FIG. 6, changes to the high level. Thus, the electric potential of the row select line WL changes to the low level. Next, when the synchronous signal FCLK supplied to the semiconductor memory device changes to the high level, the column predecode signal generation circuit described above inactivates all of its outputs. Thus, the electric potentials of all the column select lines BL change to the low level.

When the synchronous signal FCLK changes to the high level, the output signal BT changes to the low level. Thus, the row select lines WL are opened, with the electric potentials of the row select lines WL remaining at the low level. Thereafter, when the control signal RST illustrated in FIG. 1 is changed to the high level, the electric potentials of the row select lines WL and the column select lines BL are latched by the scan flip-flop circuits 112, 113. The synchronous signal SCLK is input to the scan flip-flop circuits 112, 113, so that the electric potentials of the row select lines WL and the column select lines BL are output from the 0 terminal of the final-stage flip-flop circuit 116 as a signal SO.

Even in the case of a slight short circuit in which an active one of the row select lines WL has certain resistance, the above operation can detect the abnormality by sensing the electric potential of the signal SO output to the terminal.

Even when an abnormality occurs in the row select line WL or the column select line BL which is connected to a memory cell other than the memory cells specified by the input address signals AX, AY, the first operation and the second operation can detect the abnormality. For example, when a change in electric potential occurs in a position other than positions specified by the input address signals AX, AY, the change in electric potential can be detected as an abnormality in the signal SO in FIGS. 7 and 8.

As described above, in the semiconductor memory device 10 according to the present embodiment, the row control circuit 102 and the scan flip-flop circuit 112 are connected by the row select lines WL to the memory cell array 101 provided therebetween. Thus, it is possible to detect an abnormality which occurs in any position in the route from the control circuit 100 to the scan flip-flop circuit 112.

The column/input and output control circuit 103 and the scan flip-flop circuit 113 are connected by the column select lines BL to the memory cell array 101 provided therebetween. Thus, it is possible to detect an abnormality which occurs in any position in the route from the control circuit 100 to the scan flip-flop circuit 113.

Although the present embodiment has described the case where two scan flip-flop circuits 112, 113 are provided, at least one of the scan flip-flop circuits may be provided. For example, when only the scan flip-flop circuit 112 is provided, an abnormality which may occur in the row select line WL can be detected, and when only the scan flip-flop circuit 113 is provided, an abnormality which may occur in the column select line BL can be detected.

Although the present invention has described the case where the electric fuse is used as a nonvolatile device, any write-once nonvolatile device can be used. For example, metal interconnect fusing-type fuses, fuses for breaking contacts between metal interconnect layers, antifuses for breaking gate sections of transistors, and transistor degradation-type fuses for allowing a flow of an overcurrent to transistors may be used, or electrically erasable programmable read only memory (EEPROM) cells having floating gates may be used.

In a leading process in which progress is being made for further miniaturization, the present disclosure is useful, as a circuit technology of system LSIs to which ID codes for security, processors, memories, PLL circuits, etc. are mounted, for maintaining and improving the quality in the technical field in which nonvolatile devices having in particular a large capacitance is implemented in array-type configuration.

What is claimed is:

1. A semiconductor memory device comprising:
a nonvolatile device array including write-once nonvolatile devices arranged in rows and columns;
one or more row select lines corresponding to rows of the nonvolatile device array;
a row control circuit connected to one ends of the row select lines;
one or more column select lines corresponding to columns of the nonvolatile device array;
a column control circuit connected to one ends of the column select lines;
a flip-flop circuit provided at least on a side of the nonvolatile device array opposite to the row control circuit or on a side of the nonvolatile device array opposite to the column control circuit; and
an inactivation unit configured to inactivate the row select lines or the column select lines based on a first control signal.

2. The semiconductor memory device of claim 1, wherein
the inactivation unit include a predecode signal generation circuit configured to inactivate a predecode signal to inactivate a corresponding one of the row select lines or a corresponding one of the column select lines, the predecode signal logically transitioning based on the first control signal.

3. The semiconductor memory device of claim 2, wherein
the predecode signal generation circuit inactivates the predecode signal based on the first control signal and a second control signal for selecting the nonvolatile device array.

4. The semiconductor memory device of claim 2, wherein
the predecode signal generation circuit inactivates the predecode signal based on a first synchronous signal and the first control signal.

5. The semiconductor memory device of claim 1, further comprising:
an open unit configured to open the column select lines, excluding one of the column select lines, when the column select lines are not inactivated, or the row select lines, excluding one of the row select lines, when the row select lines are not inactivated.

6. The semiconductor memory device of claim 5, wherein
the open unit includes n-type MIS transistors each having a drain connected to a corresponding one of the row select lines and a gate receiving a signal obtained by logically combining a first synchronous signal and a third control signal.

7. The semiconductor memory device of claim 6,
the open unit changes gate potentials of the n-type MIS transistors to a low level to open the row select lines, excluding an active one of the row select lines.

8. The semiconductor memory device of claim 5, wherein
the open unit includes n-type MIS transistors each having a drain connected to a corresponding one of the column select lines and a gate receiving a signal obtained by logically combining a first synchronous signal and a third control signal.

9. The semiconductor memory device of claim 8, wherein
the open unit changes gate potentials of the n-type MIS transistors to a low level to open the column select lines, excluding an active one of the column select lines.

10. The semiconductor memory device of claim 1, wherein
the flip-flop circuit latches electric potentials of the row select lines or the column select lines based on a fourth control signal.

11. The semiconductor memory device of claim 1, wherein
the flip-flop circuit includes flip-flop circuits provided on a side of the nonvolatile device array opposite to the row control circuit and on a side of the nonvolatile device array opposite to the column control circuit.

12. The semiconductor memory device of claim 1, wherein
the nonvolatile device is an electric fuse made of a gate material of a transistor.
